(19) United States
(12) Patent Application Publication
(10) Pub. No.: US 2024/0379621 A1
(43) Pub. Date: Nov. 14, 2024

(54) MEMORY SYSTEM INCLUDING SEMICONDUCTOR CHIPS

(71) Applicant: SK hynix Inc., Icheon-si (KR)

(72) Inventor: Dong Sop LEE, Icheon-si (KR)

(21) Appl. No.: 18/483,489

(22) Filed: Oct. 9, 2023

(30) Foreign Application Priority Data
May 8, 2023 (KR) 10-2023-0058947

(51) Int. Cl. H01L 25/065; H01L 23/00; H10B 80/00

(52) U.S. Cl. CPC H01L 25/0657; H01L 24/05; H01L 24/46; H10B 80/00; H01L 2224/04042; H01L 2224/46; H01L 2225/06506; H01L 2924/1203; H01L 2924/1434

(57) ABSTRACT

In an embodiment of the disclosed technology, a semiconductor system may include a substrate; a first memory chip supported by the substrate, wherein the first memory chip includes a first main pad structured to be electrically connected to an interconnection structure disposed outside the first memory chip and a first sub pad electrically connected to the first main pad; and one or more second memory chips supported by the substrate, wherein each of the one or more second memory chips includes a second main pad structured to be electrically connected to an interconnection structure disposed outside the first memory chip and a second sub pad electrically connected to the second main pad, and the second main pad or the second sub pad included in one second memory chip of the one or more second memory chips is electrically connected to the first sub pad by a first internal interconnection structure.

### CROSS-REFERENCE TO RELATED APPLICATION

This patent document claims the priority and benefits of Korean Patent Application No. 10-2023-0058947 filed on May 8, 2023, which is incorporated herein by reference in its entirety.

### TECHNICAL FIELD

Various embodiments generally relate to a semiconductor chip and a semiconductor system such as a memory system.

### BACKGROUND

A semiconductor system may include semiconductor chips, such as semiconductor memory chips, and various integrated circuits to transmit electrical signals or power to the semiconductor chips. The semiconductor chips and the integrated circuits may be mounted on a substrate and be electrically connected to each other.

With the miniaturization of electronic devices, the feature sizes of semiconductor chips decrease and the volume of a semiconductor system also decrease. In addition, it is required that a semiconductor system can process a large amount of data at a high speed.

### SUMMARY

Various embodiments of the disclosed technology are directed to providing a semiconductor system capable of improving signal transmission speed between a semiconductor chip and an integrated circuit included in the semiconductor system and processing high-capacity data at high speed.

In an embodiment, a semiconductor system may include a substrate; a first memory chip supported by the substrate, wherein the first memory chip includes a first main pad structured to be electrically connected to an interconnection structure disposed outside the first memory chip and a first sub pad electrically connected to the first main pad; and one or more second memory chips supported by the substrate, wherein each of the one or more second memory chips includes a second main pad structured to be electrically connected to an interconnection structure disposed outside the first memory chip and a second sub pad electrically connected to the second main pad, and the second main pad or the second sub pad included in one second memory chip of the one or more second memory chips is electrically connected to the first sub pad by a first internal interconnection structure.

In an embodiment, a semiconductor chip may include a main data pad having a first electrostatic discharge characteristic, and configured to receive a data signal from an external device outside the semiconductor chip; and a sub data pad having a second electrostatic discharge characteristic lower than the first electrostatic discharge characteristic, and electrically connected to the main data pad, and configured to transmit the data signal to circuitry in semiconductor chip through sub data pad.

In an embodiment, a semiconductor system may include: a package substrate; and a first memory chip and one or more second memory chips on the package substrate, wherein the first memory chip includes a first main pad and a first sub pad which is electrically connected to the first main pad, and wherein each of the one or more second memory chips includes a second main pad and a second sub pad which is electrically connected to the second main pad, and the second main pad or the second sub pad included in any one of the one or more second memory chips is electrically connected to the first sub pad by a first internal interconnection structure.

In an embodiment, a semiconductor chip may include: a main data pad having a first electrostatic discharge characteristic, and supplied with a data signal from the outside; and a sub data pad having a second electrostatic discharge characteristic lower than the first electrostatic discharge characteristic, electrically connected to the main data pad, and configured to transfer the data signal to the inside.

According to the embodiments of the disclosed technology, data processing performance by a semiconductor system may be improved by increasing the number of semiconductor chips included in the semiconductor system and reducing signal delay between a semiconductor chip and an integrated circuit.

### BRIEF DESCRIPTION OF THE DRAWINGS

FIG. 1 illustrates an example of components included in a semiconductor system based on an embodiment of the disclosed technology.

FIG. 2 illustrates an example structure of a semiconductor system that includes memory chips and circuitry disposed in the semiconductor system based on an embodiment of the disclosed technology.

FIGS. 3A and 3B illustrate example structures of memory pad units disposed in the memory chips based on the embodiment of the disclosed technology.

FIGS. 4 and 5 illustrate examples of a connection structure between memory chips and a controller included in a semiconductor system based on an embodiment of the disclosed technology and structures of memory pad units disposed in the memory chips.

FIGS. 6 and 7 are diagrams illustrating other examples of a connection structure between memory chips and a controller included in a semiconductor system based on an embodiment of the disclosed technology and structures of memory pad units disposed in the memory chips.

FIGS. 8 and 9 are diagrams illustrating still other examples of a connection structure between memory chips and a controller included in a semiconductor system based on an embodiment of the disclosed technology and structures of memory pad units disposed in the memory chips.

FIG. 10 is a diagram illustrating an example of a connection structure between memory chips and a power management integrated circuit included in a semiconductor system based on an embodiment of the disclosed technology.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein may be omitted.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Hereinafter, various embodiments of the present disclosure will be described in detail with reference to accompanying drawings.

To reduce the volume of a semiconductor system such as a memory system and to improve its data processing performance, the disclosed technology can be implemented in some embodiments to provide semiconductor chips and semiconductor systems (e.g., memory systems) that include integrated circuits and layout and connection structures that can transmit a large amount of data at a high speed, while minimizing the volume of the semiconductor systems.

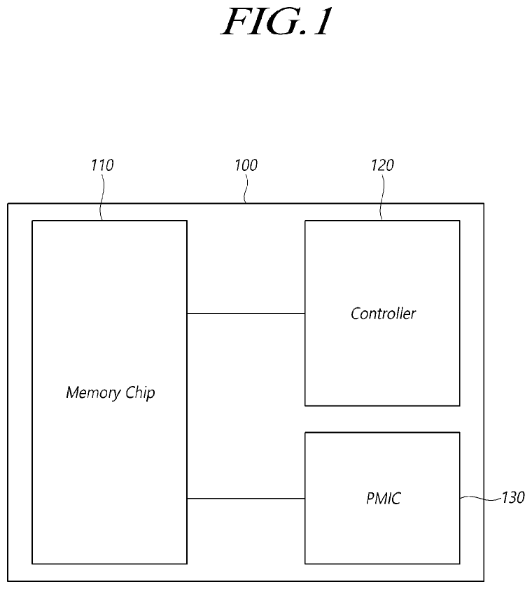

FIG. 1 is a diagram illustrating an example of components included in a semiconductor system 100 based on an embodiment of the disclosed technology.

Referring to FIG. 1, the semiconductor system 100 based on the embodiment of the disclosed technology may include at least one semiconductor chip and various integrated circuits which supply signals or power to the semiconductor chip.

For example, the semiconductor system 100 may include at least one memory chip 110. The semiconductor system 100 may include a controller 120 which supplies a data signal, a control signal, etc. to the memory chip 110. The semiconductor system 100 may include a power management integrated circuit 130 which supplies power to the memory chip 110.

For example, example of the memory chip 110 may include a NAND flash memory, a 3D NAND flash memory, a NOR flash memory, a resistive random access memory (RRAM), a phase-change random access memory (PRAM), a magnetoresistive random access memory (MRAM), a ferroelectric random access memory (FRAM) and a spin transfer torque random access memory (STT-RAM). The memory chip 110 may have a three-dimensional array structure. In some embodiments of the disclosed technology, the memory chip 110 may be a flash memory that includes a conductive floating gate as a charge storage layer. In some embodiments of the disclosed technology, the memory chip 110 may be a charge trap flash (CTF) that includes a dielectric layer as a charge storage layer.

The memory chip 110 may include a plurality of memory cells configured to store data. The memory chip 110 may include various circuits for performing memory operations such as writing data to the plurality of memory cells, erasing data in the plurality of memory cells, or reading data from the plurality of memory cells.

The memory chip 110 may receive data signals such as a command and an address from the controller 120. The memory chip 110 may access an area of the plurality of memory cells selected by the address. The memory chip 110 may perform, in response to the command, an operation on the area selected by the address.

The controller 120 may control program, read and erase operations on the memory chip 110. The controller 120 may include a control circuit to control the operation of the memory chip 110 by performing overall control operations of the controller 120. The control circuit may include, for example, a processor, a working memory and so forth, and may optionally include an error detection and correction circuit.

The power management integrated circuit 130 may provide a voltage for the memory chip 110 to perform its memory operations. The power management integrated circuit 130 may provide a voltage for the controller 120 to perform operations on the memory chip 110.

The memory chip 110 may perform programming, erasing and reading operations on its memory cells by using a data signal received from the controller 120 and a voltage provided from the power management integrated circuit 130.

In some implementations, the semiconductor system 100 may further include at least one additional integrated circuit other than the integrated circuits discussed above. Also, the semiconductor system 100 may include two or more memory chips 110 to process a larger amount of data.

When the semiconductor system 100 include two or more memory chips 110, the two or more memory chips 110 may be disposed on the same plane or may be disposed in a stacked structure.

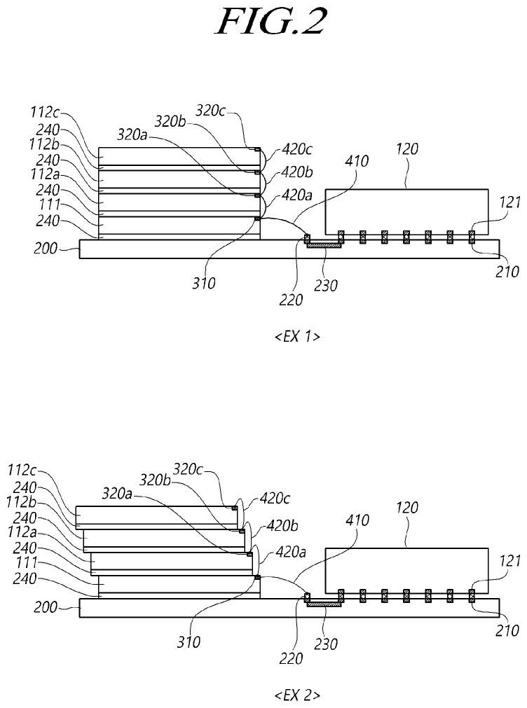

FIG. 2 is a diagram illustrating an example of a structure in which memory chips 110 and a circuit are disposed in a semiconductor system 100 based on an embodiment of the disclosed technology.

Referring to FIG. 2, the semiconductor system 100 may include a substrate (e.g., package substrate) 200 and a semiconductor chip and various integrated circuits disposed on the substrate 200. FIG. 2 illustrates, as an example, a cross-sectional of a structure that includes four memory chips 110 and a controller 120 disposed on the substrate 200.

A first memory chip 111 may be disposed on the substrate 200. One or more second memory chips 112 may be disposed on the substrate 200. In some embodiments of the disclosed technology, the first memory chip 111 may be a master memory chip. In some embodiments of the disclosed technology, the second memory chip 112 may a slave memory chip. In some implementations, the term “master memory chip” can be used to indicate a memory chip that is directly connected to the controller 120 by a wire. In some implementations, the term “master memory chip” can be used to indicate a memory chip that is connected to the controller 120 through a semiconductor chip that is not a memory chip. The master memory chip can communicate with the controller directly or through the semiconductor chip. In some implementations, the term “slave memory chip” can be used to indicate a memory chip that is connected to the master memory chip by a wire. In some implementations, the slave memory chip can communicate with the controller 120 through a wire connected to the master memory chip. In some implementations, the term “master memory chip” can be used to indicate a memory chip that can control at least part of operations of other devices such as the slave memory chip, and the term “slave memory chip” can be used to indicate a memory chip that can be controlled by the master memory chip. In some implementations, the term “master memory chip” can be used to indicate a memory chip that can serve as a communication hub for other devices such as the slave memory chip, and the term “slave memory chip” can be used to indicate a memory chip that uses the master memory chip to communicate with an external device.

The first memory chip 111 may be mounted on the substrate 200 by using an adhesive member 240. The one or more second memory chips 112 may be disposed on the first memory chip 111. For example, the one or more second memory chips 112 may be stacked on the first memory chip 111. FIG. 2 illustrates, as an example, three second memory chips 112a, 112b and 112c only, and the three second memory chips 112a, 112b and 112c may be disposed on the first memory chip 111 by adhesive members 240.

The controller 120 may be disposed on the substrate 200. The substrate 200 may include substrate pads 210 on the upper surface of the substrate 200. The controller 120 may include chip pads 121 on the lower surface of the controller 120.

The substrate pads 210 of the substrate 200 and the chip pads 121 of the controller 120 may be electrically connected to each other through, for example, conductor balls (conductor ball) 220.

The memory chips 110 and the controller 120 on the substrate 200 may be electrically connected to each other through conductor balls (e.g., package ball) 220 and wires.

For example, each of the memory chips 110 may include a memory pad unit to which a data signal supplied from the controller 120 is applied. For example, the first memory chip 111 may include a first memory pad unit 310. The three second memory chips 112a, 112b and 112c may include second memory pad units 320a, 320b and 320c, respectively.

Each of the first memory pad unit 310 and second memory pad units 320 may include two or more pads.

The first memory pad unit 310 may be electrically connected to the conductor balls 220 through, for example, external interconnection structures (e.g., interconnects in a semiconductor system) 410. The conductor balls 220 may be electrically connected to the controller 120 through the substrate pads 210 and interconnection structure 230 disposed in the substrate 200. In some implementations, the conductor balls 220 are connected to the controller 120 through the interconnection structure 230 disposed in the substrate 200 by way of example, and an electrical connection structure of the conductor balls 220 and the controller 120 may be implemented in various ways.

The second memory pad units 320 may not be directly connected to the conductor balls 220 electrically connected to the controller 120. The second memory pad units 320 may be electrically connected to a memory pad unit included in another memory chip 110, through internal interconnection structures.

For example, the second memory pad unit 320a included in the second memory chip 112a on the first memory chip 111 may be electrically connected to the first memory pad unit 310, which is included in the first memory chip 111, by a first internal interconnection structure 420a.

The second memory pad unit 320b included in the second memory chip 112b, which is positioned second from the first memory chip 111, may be electrically connected to the second memory pad unit 320a included in the second memory chip 112a, which is positioned first from the first memory chip 111, by a first internal interconnection structure 420b. The second memory pad unit 320c included in the second memory chip 112c, which is disposed uppermost, may be electrically connected to the second memory pad unit 320b included in the second memory chip 112b, which is positioned second from the bottom, by a first internal interconnection structure 420c.

Referring to FIG. 2, in some implementations where the memory chips 110 are connected by an internal interconnection structure, in one example, the memory chips 110 are vertically aligned as shown in Example 1<EX 1>, or in another example, the memory chips 110 are shifted in a lateral direction as shown in Example 2<EX 2>.

In the structure in which the two or more memory chips 110 are disposed in the semiconductor system 100, since the connection between the first memory chip 111 (e.g., master memory chip) and the controller 120 is made by the external interconnection structure 410 and the connection between the first memory chip 111 (e.g., master memory chip) and the second memory chip 112 (e.g., slave memory chip) and the connection between the second memory chips 112 are made by the first internal interconnection structures 420, the connection structure between the memory chips 110 and the controller 120 may be easily implemented.

In a memory pad unit included in each memory chip 110, a pad that is connected to the external interconnection structure 410 may be separately formed from a pad that is connected to the internal interconnection structure 420. By forming the pad connected to the external interconnection structure 410 separately from the pad connected to the internal interconnection structure 420, the connection between the memory pad unit included in the memory chip 110 and the controller 120 may be easily implemented, and it is possible to prevent or reduce deterioration of signal transmission/reception performance that otherwise would have been caused by the capacitance of wires and pads through which signals are transmitted and received.

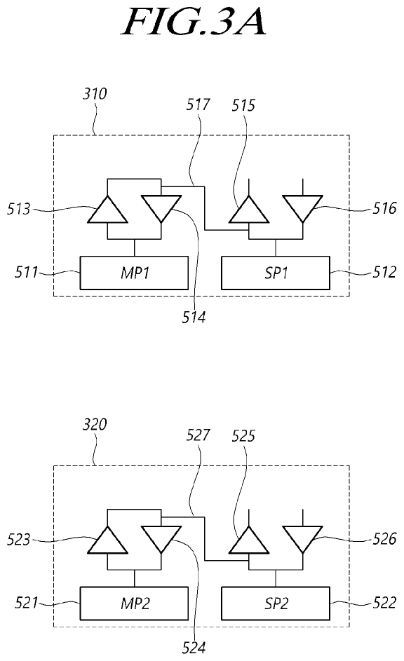

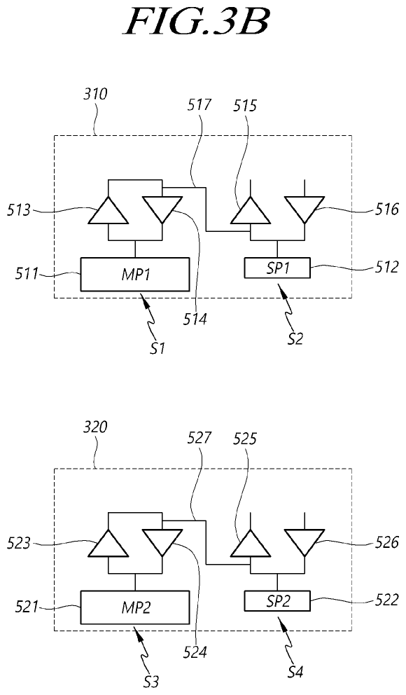

FIGS. 3A and 3B are diagrams illustrating examples of structures of the memory pad units disposed in the memory chips 110 based on the embodiment of the disclosed technology.

Referring to FIG. 3A, the first memory pad unit 310 included in the first memory chip 111 may include a first main pad 511 and a first sub pad 512. The second memory pad unit 320 included in the second memory chip 112 may include a second main pad 521 and a second sub pad 522. In some implementations, the term “pad” may be used to indicate a contact area structured to be electrically connected to an interconnection structure.

The structure of the first memory pad unit 310 may be the same as or similar to the structure of the second memory pad unit 320. For example, the size and shape of the second main pad 521 may be the same as or similar to the size and shape of the first main pad 511. The size and shape of the second sub pad 522 may be the same as or similar to the size and shape of the first sub pad 512.

The first main pad 511 included in the first memory pad unit 310 may be, for example, a pad that is connected to the external interconnection structure 410. The first sub pad 512 included in the first memory pad unit 310 may be, for example, a pad that is connected to an internal interconnection structure.

One of the second main pad 521 and the second sub pad 522 included in the second memory pad unit 320 may be a pad that is connected to an internal interconnection structure. In some implementations, each of the second main pad 521 and the second sub pad 522 may be connected to a pad that is included in the first memory pad unit 310 or may be connected to a pad that is included in another second memory pad unit 320.

The first main pad 511 and the first sub pad 512 disposed in the first memory pad unit 310 may form a repeater structure to pass a signal received by the first main pad 511 to the first sub pad 512. The second main pad 521 and the second sub pad 522 disposed in the second memory pad unit 320 may form a repeater structure to pass a signal received by the second main pad 521 to the second sub pad 522. The repeater structure of the first memory pad unit 310 and the repeater structure of the second memory pad unit 320 may be the same as or similar to each other.

The first memory pad unit 310 may include a first main input diode 513 and a first main output diode 514, which are connected to the first main pad 511. The first memory pad unit 310 may include a first sub input diode 515 and a first sub output diode 516, which are connected to the first sub pad 512. The first memory pad unit 310 may include a first connection part 517.

The output terminal of the first main input diode 513 may be electrically connected to the input terminal of the first main output diode 514.

The input terminal of the first main output diode 514 may be electrically connected to the input terminal of the first sub input diode 515 through the first connection part 517.

A data signal applied to the first main pad 511 included in the first memory pad unit 310 may be transferred to the first sub pad 512 through the first connection part 517. The data signal may be supplied to the inside of the first memory chip 111 through the first sub input diode 515. The data signal may be transferred to the second memory pad unit 320 included in the second memory chip 112 through an internal interconnection structure connected to the first sub pad 512. The second memory pad unit 320 may include a second main

input diode 523 and a second main output diode 524, which are connected to the second main pad 521. The second memory pad unit 320 may include a second sub input diode 525 and a second sub output diode 526, which are connected to the second sub pad 522. The second memory pad unit 320 may include a second connection part 527.

The second main pad 521 or the second sub pad 522 included in the second memory pad unit 320 may be used to receive a data signal transferred from the memory pad unit of another memory chip 110.

When the second main pad 521 included in the second memory pad unit 320 receives the data signal, the data signal may be transferred to the second sub pad 522 through the second connection part 527. The data signal may be transferred to circuitry in the second memory chip 112 through the second sub input diode 525, and may be transferred to the second memory pad unit 320 included in another second memory chip 112, through an internal interconnection structure connected to the second sub pad 522. Even in the case where a data signal is transmitted to the second sub pad 522 without passing through the second main pad 521, the data signal may be similarly transferred to the circuitry in the corresponding second memory chip 112 and another second memory chip 112.

Since a main pad that directly receives a data signal from the controller 120 and a sub pad that transfers the data signal between the memory chips 110 are differentiated and the main pad and the sub pad are connected through a connection structure, the characteristics and/or sizes of the main pad and the sub pad may be different from each other.

For example, the electrostatic discharge characteristic of each of the first sub pad 512 and the second sub pad 522 may be lower than the electrostatic discharge characteristic of each of the first main pad 511 and the second main pad 521. In some implementations, the term “electrostatic discharge characteristic” can be used to indicate a durability from the external electrostatic. For example, the durability from the external electrostatic can be varied according to a material consisting of the main pad or the sub pad. Furthermore, an additional component can be included in the main pad to enhance the durability from the external electrostatic. A material or layers of the main pad can be different from those of the sub pad to enhance the durability from the external electrostatic so that it is higher than the durability of the sub pad.

In some implementations, as illustrated in FIG. 3B, a size S2 of the first sub pad 512 may be smaller than a size S1 of the first main pad 511. A size S4 of the second sub pad 522 may be smaller than a size S3 of the second main pad 521. In this case, the size S3 of the second main pad 521 may be the same as the size S1 of the first main pad 511. The size S4 of the second sub pad 522 may be the same as the size S2 of the first sub pad 512.

As such, since wires and pads that connect the memory chip 110 and the controller 120 and wires and pads that connect the memory chips 110 are differentiated, it is possible to easily implement a connection structure between the memory chip 110 and the controller 120 and prevent or reduce a signal delay that otherwise would have been caused by the parasitic capacitance of a transmission path of a data signal.

When the plurality of memory chips 110 is disposed in the semiconductor system 100, a connection structure can be formed by a main pad and a sub pad included in each of the plurality of memory chips 110, and the semiconductor system 100 can process a large amount of data at a high speed by reducing or minimizing the parasitic capacitance of a transmission path of a data signal.

In the semiconductor system 100 including the plurality of memory chips 110, a connection structure by the external interconnection structure 410 and an internal interconnection structure may be implemented in various ways.

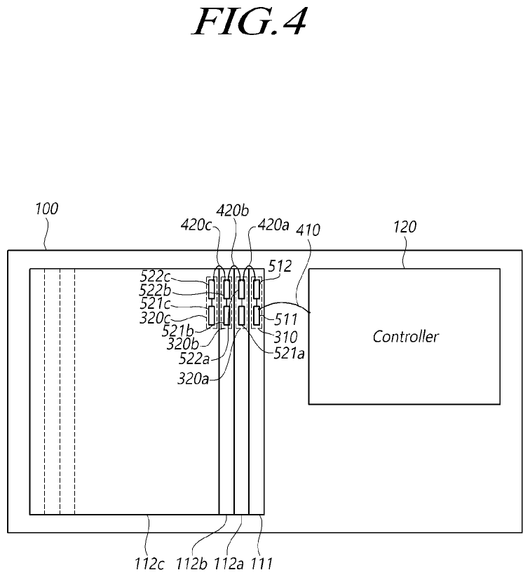

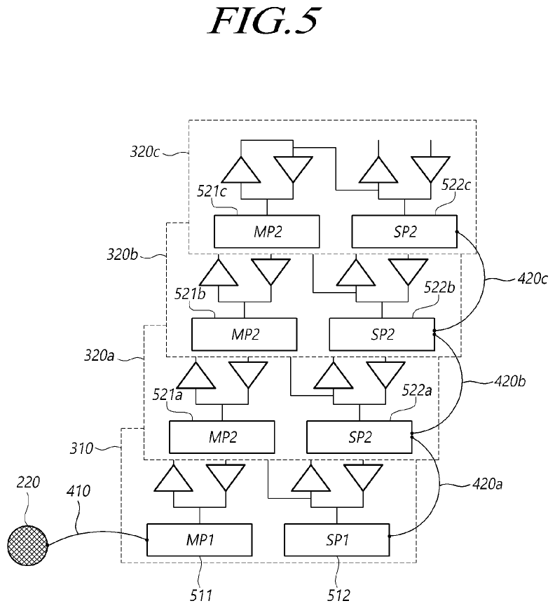

FIGS. 4 and 5 are diagrams illustrating examples of a connection structure between memory chips 110 and a controller 120 included in a semiconductor system 100 based on an embodiment of the disclosed technology and structures of memory pad units disposed in the memory chips 110.

In FIGS. 4 and 5, a case where the semiconductor system 100 includes one first memory chip 111 and three second memory chips 112a, 112b and 112c is illustrated as an example.

The first memory chip 111 as the memory chip 110 which is connected to the controller 120 through an external interconnection structure 410 may be referred to as a master memory chip. Second memory chips 112 as the memory chips 110 which are supplied with a data signal through an internal interconnection structure may be referred to as slave memory chips.

The first memory chip 111 may be disposed on a substrate (e.g., package substrate) 200, and the three second memory chips 112a, 112b and 112c may be disposed on the first memory chip 111.

The first memory chip 111 may include a conductive area such as a first memory pad unit 310. The first memory pad unit 310 may include a first main pad 511 and a first sub pad 512.

The first main pad 511 may be electrically connected to the controller 120 through the external interconnection structure 410. The external interconnection structure 410 may be directly connected to, for example, each of the first main pad 511 and a conductor ball 220, and may electrically connect the first main pad 511 and the conductor ball 220. The external interconnection structure 410 may be electrically connected to the controller 120 through the conductor ball 220. The three second memory chips 112a, 112b and 112c may include second memory pad units 320a, 320b and 320c, respectively. Each of second memory pad units 320 may include a second main pad 521 and a second sub pad 522.

A second sub pad 522a of the second memory pad unit 320a disposed in the second memory chip 112a may be electrically connected to the first sub pad 512 of the first memory pad unit 310 disposed in the first memory chip 111 by a first internal interconnection structure 420a.

The second sub pad 522a of the second memory pad unit 320a disposed in the second memory chip 112a may be electrically connected to a second sub pad 522b of the second memory pad unit 320b disposed in another second memory chip 112b by a first internal interconnection structure 420b.

The second sub pad 522b of the second memory pad unit 320b disposed in the second memory chip 112b may be electrically connected to a second sub pad 522c of the second memory pad unit 320c disposed in still another second memory chip 112c by another first internal interconnection structure 420c.

The connection between adjacent second memory chips 112 or the connection between the first memory chip 111 and the second memory chip 112 which are adjacent to each other may be made by the first internal interconnection structure 420.

A data signal transmitted from the controller 120 may be transmitted to the first main pad 511 of the first memory pad unit 310 disposed in the first memory chip 111 through the external interconnection structure 410. The data signal transmitted to the first main pad 511 may be transmitted to the first sub pad 512 through a first connection part 517 and to the circuitry in the first memory chip 111.

The data signal transmitted to the first main pad 511 may be transmitted to the second sub pad 522a of the second memory pad unit 320a disposed in the second memory chip 112a through the first sub pad 512.

The data signal transmitted to the second sub pad 522a may be transmitted to the circuitry in the second memory chip 112a. The data signal transmitted to the second sub pad 522a may be transmitted to the second sub pad 522b of the second memory pad unit 320b disposed in another second memory chip 112b.

The data signal transmitted to the second sub pad 522b may be transmitted to the inside of the second memory chip 112b. The data signal transmitted to the second sub pad 522b may be transmitted to the second sub pad 522c of the second memory pad unit 320c disposed in another second memory chip 112c.

The data signal transmitted to the second sub pad 522c may be transmitted to the circuitry in the second memory chip 112c.

As such, a pad that is connected to the external interconnection structure 410 to transmit a data signal from the outside of the memory chips 110 and a pad that is connected to the first internal interconnection structure 420 to transmit a data signal between the memory chips 110 may be differentiated. The pad connected to the first internal interconnection structure 420 to transmit a data signal between the memory chips 110 may be designed to have an electrostatic discharge characteristic lower than the electrostatic discharge characteristic of the pad connected to the external interconnection structure 410.

The size of the first sub pad 512 and the second sub pad 522 which are connected to the first internal interconnection structure 420 may be designed to be smaller than the first main pad 511 or the second main pad 521, and thus it is possible to reduce the parasitic capacitance that otherwise would have been caused by a wire and a pad through which a data signal is transmitted.

In the case where each data pad included in each memory chip 110 is connected to the controller 120 through the external interconnection structure 410, since each data pad should be designed to have a high electrostatic discharge characteristic, the area of the pad may increase, and thus large parasitic capacitance may be formed.

Since a pad connected to the external interconnection structure 410 and a pad for the connection between the memory chips 110 are differentiated, the pad for the connection between the memory chips 110 may be designed to be small, and the parasitic capacitance by a wire and a pad that constitute a path through which a data signal is transmitted may be reduced, and the transmission delay of the data signal may decrease.

In some implementations, the first internal interconnection structure 420 and the second sub pad 522 may form a path that carries a data signal transmitted between the memory chips 110. In some implementations, the second main pad 521 may form a path that carries a data signal transmitted between the memory chips 110.

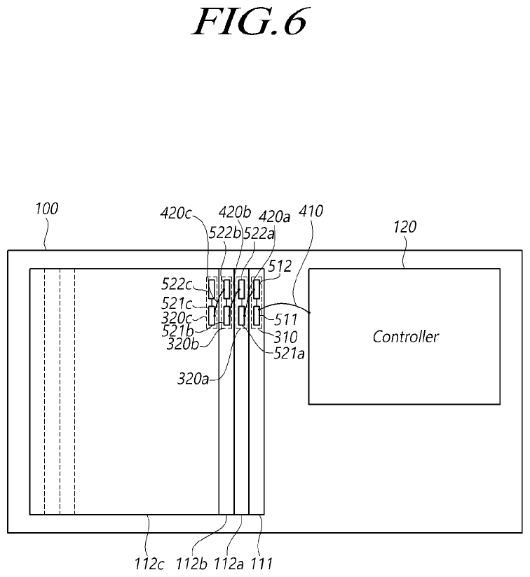

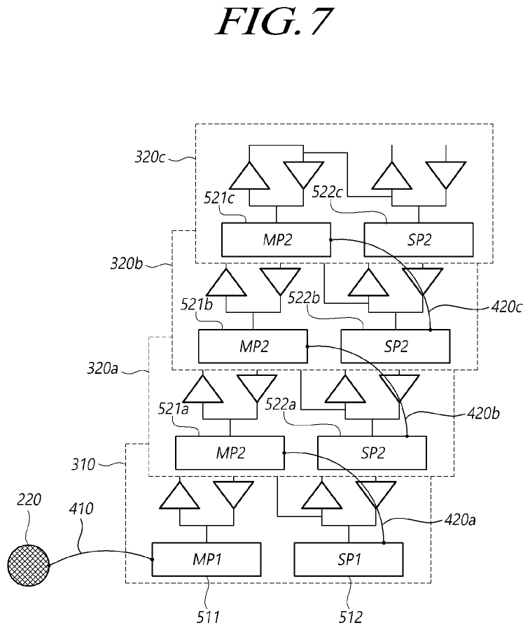

FIGS. 6 and 7 are diagrams illustrating other examples of a connection structure between memory chips 110 and a controller 120 included in a semiconductor system 100 based on an embodiment of the disclosed technology and structures of memory pad units disposed in the memory chips 110.

Referring to FIGS. 6 and 7, a case where one first memory chip 111 and three second memory chips 112a, 112b and 112c are disposed in the semiconductor system 100 is illustrated as an example. The first memory chip 111 may include a first main pad 511 and a first sub pad 512. Each of second memory chips 112 may include a second main pad 521 and a second sub pad 522.

The first main pad 511 of a first memory pad unit 310 disposed in the first memory chip 111 may be electrically connected to the controller 120 through an external interconnection structure 410.

The first sub pad 512 of the first memory pad unit 310 disposed in the first memory chip 111 may be electrically connected to a second main pad 521a of a second memory pad unit 320a disposed in the second memory chip 112a through a first internal interconnection structure 420a.

A second sub pad 522a of the second memory pad unit 320a disposed in the second memory chip 112a may be electrically connected to a second main pad 521b of a second memory pad unit 320b disposed in another second memory chip 112b through another first internal interconnection structure 420b.

A second sub pad 522b of the second memory pad unit 320b disposed in the second memory chip 112b may be electrically connected to a second main pad 521c of a second memory pad unit 320c disposed in another second memory chip 112c through another first internal interconnection structure 420c.

The electrical connection between the second main pad 521 of one of adjacent second memory chips 112 and the second sub pad 522 of the other of the adjacent second memory chips 112 may be made by the first internal interconnection structure 420. In addition, the electrical connection between the first sub pad 512 of the first memory chip 111 and the second main pad 521 of the second memory chip 112 which are adjacent to each other may be made by the first internal interconnection structure 420.

In some implementations, the first internal interconnection structure 420 may not be connected to the first main pad 511 disposed in the first memory chip 111, to which the external interconnection structure 410 is connected.

A data signal transmitted to the first main pad 511 of the first memory pad unit 310 disposed in the first memory chip 111 through the external interconnection structure 410 may be transmitted to the first sub pad 512 through a first connection part 517.

The data signal transmitted to the first sub pad 512 may be transmitted to the second main pad 521a of the second memory pad unit 320a disposed in the second memory chip 112a through the first internal interconnection structure 420a. The data signal applied to the first main pad 521a may be transmitted to the second sub pad 522a through a second connection part 527.

Similarly, between the second memory chips 112, a data signal may be transmitted through the second sub pad 522, the first internal interconnection structure 420, the second main pad 521 and the second connection part 527.

In some implementations, the first internal interconnection structure 420 may not connect between the second sub pads 522 disposed in the second memory chips 112, but may connect between the second sub pad 522 and the first main pad 521 disposed in the second memory chips 112.

In the case where all the second sub pads 522 are connected by the first internal interconnection structures 420, if the number of second memory chips 112 increases and thus the number of second sub pads 522 electrically connected to each other increases, parasitic capacitance caused by the second sub pads 522 may also increase.

Since the first internal interconnection structure 420 connects adjacent second memory chips 112 through the second main pad 521 and the second sub pad 522 to prevent all the second sub pads 522 from being electrically connected to each other, it is possible to reduce or minimize the parasitic capacitance in the connection structure by the first internal interconnection structures 420 when the number of second memory chips 112 increases.

In some implementations, the second main pad 521 and the second sub pad 522 of the second memory chips 112 are connected by an internal interconnection structure and additionally the second sub pads 522 of the second memory chips 112 are connected by an internal interconnection structure to increase the signal transmission speed while reducing the parasitic capacitance caused by a path through which a data signal is transmitted.

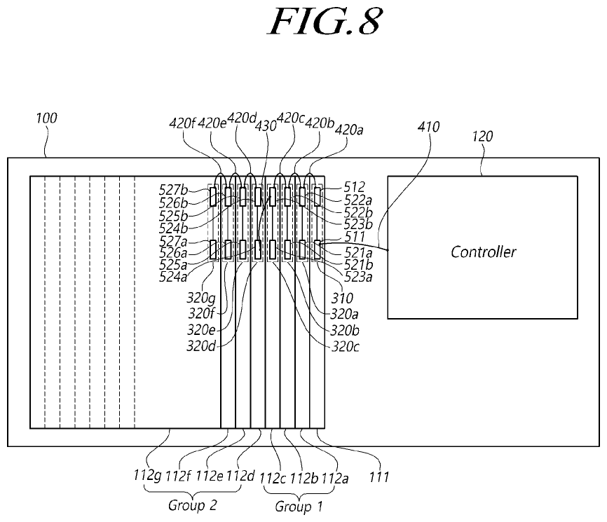

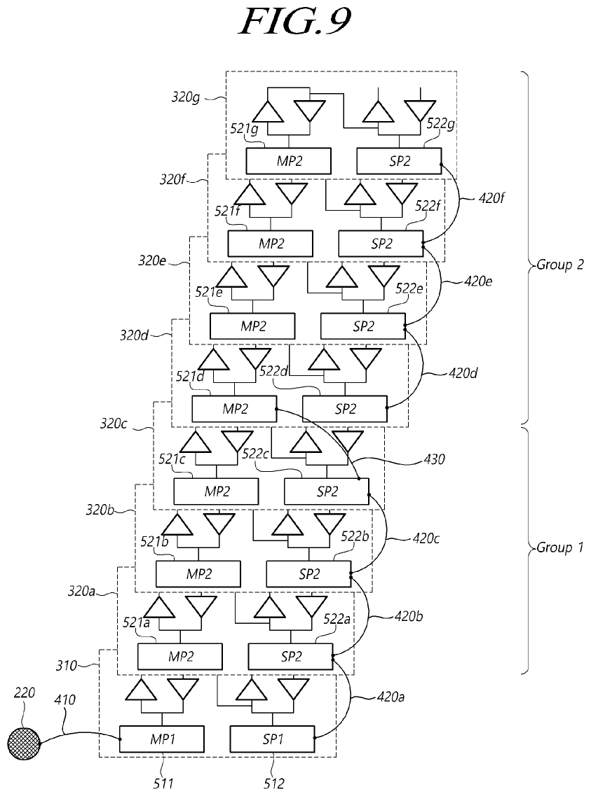

FIGS. 8 and 9 are diagrams illustrating still other examples of a connection structure between memory chips 110 and a controller 120 included in a semiconductor system 100 based on an embodiment of the disclosed technology and structures of memory pad units disposed in the memory chips 110.

Referring to FIGS. 8 and 9, a case where eight memory chips 110 are disposed in the semiconductor system 100 is illustrated as an example. The semiconductor system 100 may include one first memory chip 111 and seven second memory chips 112a, 112b, 112c, 112d, 112e, 112f and 112g. Second memory chips 112 may be divided into second memory chips 112a, 112b and 112c which are included in a first group and second memory chips 112d, 112e, 112f and 112g which are included in a second group.

The first memory chip 111 may include a first main pad 511 to which a data signal is applied and a first sub pad 512 which is electrically connected to the first main pad 511.

Each of the second memory chips 112 may include a second main pad 521 and a second sub pad 522 which is electrically connected to the second main pad 521.

The first main pad 511 included in the first memory chip 111 may be electrically connected to an external interconnection structure 410. The external interconnection structure 410 may be electrically connected to the controller 120 through a conductor ball 220. A data signal transmitted by the controller 120 may be transmitted to the first main pad 511 through the external interconnection structure 410.

The first sub pad 512 included in the first memory chip 111 may be electrically connected to the second main pad 521 or the second sub pad 522 included in the second memory chip 112 through a first internal interconnection structure 420. For example, the first sub pad 512 may be electrically connected to a second sub pad 522a of the second memory chip 112a through a first internal interconnection structure 420a.

The second main pads 521 or the second sub pads 522 included in adjacent second memory chips 112 may be electrically connected to each other by an internal interconnection structure.

For example, the second sub pads 522 which are included in the same group and are included in adjacent second memory chips 112 may be electrically connected by the first internal interconnection structure 420.

Second sub pads 522a, 522b and 522c included in the second memory chips 112a, 112b and 112c, respectively, included in the first group may be electrically connected by first internal interconnection structures 420b and 420c. Second sub pads 522d, 522e, 522f and 522g included in the second memory chips 112d, 112e, 112f and 112g, respectively, included in the second group may be electrically connected by first internal interconnection structures 420d, 420e and 420f.

The second memory chips 112 included in different groups may be electrically connected through the second main pad 521 and the second sub pad 522.

For example, the second sub pad 522c disposed in the second memory chip 112c, which is one of the second memory chips 112 included in the first group, and a second main pad 521d disposed in the second memory chip 112d, which is one of the second memory chips 112 included in the second group, may be electrically connected by a second internal interconnection structure 430.

The second sub pad 522c of the second memory chip 112c and the second sub pad 522d of the second memory chip 112d may be connected to the second sub pads 522 in the same groups but may not be connected to each other.

A data signal transmitted to the first main pad 511 through the external interconnection structure 410 may be transmitted to the first sub pad 512 through a first connection part 517. The data signal transmitted to the first sub pad 512 may be transmitted to the respective second memory chips 112a, 112b and 112c through the second sub pads 522a, 522b and 522c and the first internal interconnection structures 420a, 420b and 420c in the first group.

The data signal transferred to the second sub pad 522c of the second memory chip 112c may be transmitted to the second main pad 521d of the second memory chip 112d through the second internal interconnection structure 430.

The data signal transmitted to the second main pad 521d may be transmitted to the second sub pad 522d through a second connection part 527 included in a second memory pad unit 320d.

The data signal transmitted to the second sub pad 522d may be transmitted to the respective second memory chips 112e, 112f and 112g through the second sub pads 522d, 522e, 522f and 522g included in the second memory chips 112d, 112e, 112f and 112g included in the second group the first internal interconnection structures 420d, 420e and 420f connecting the second sub pads 522d, 522e, 522f and 522g.

Since a data signal transmission path between the memory chips 110 is formed through sub pads exhibiting a smaller parasitic capacitance than main pads, the delay in the transmission speed of data to the plurality of memory chips 110 may decrease.

When the number of memory chips 110 increases, since a data signal transmission path through sub pads is formed based on a group of a predetermined number of memory chips 110, it is possible to reduce or minimize the parasitic capacitance that can be caused by the increase in the number of sub pads.

By avoiding forming a data signal transmission path between the memory chips 110 through main pads and sub pads, it is possible to provide a connection structure between the memory chips 110 to improve the data transmission speed while minimizing the delay when data is transmitted through the main pads, connection parts and the sub pads.

The memory chips 110 may include pads used for power supply, in addition to pads for data signal transmission, and a connection structure between the pads for power supply and a wire may be different from a connection structure between the pads for data signal transmission and a wire.

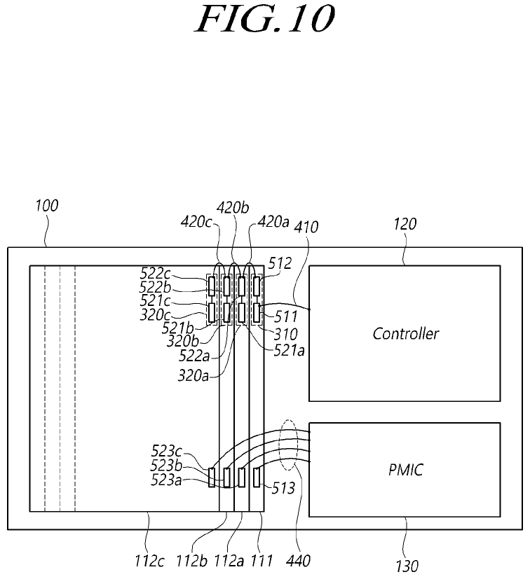

FIG. 10 is a diagram illustrating an example of a connection structure between memory chips 110 and a power management integrated circuit 130 included in a semiconductor system 100 based on an embodiment of the disclosed technology.

Referring to FIG. 10, a first memory chip 111 and second memory chips 112a, 112b and 112c may be disposed in the semiconductor system 100.

Integrated circuits such as a controller 120 and the power management integrated circuit 130 may be disposed in the semiconductor system 100.

Each of the first memory chip 111 and the second memory chips 112a, 112b and 112c may include a memory pad unit for data signal transmission from the controller 120. The first memory chip 111 may include a first main pad 511 and a first sub pad 512. Each of the second memory chips 112a, 112b and 112c may include a second main pad 521 and a second sub pad 522.

The first memory chip 111 may be connected to an external interconnection structure 410 through the first main pad 511 to be electrically connected to the controller 120. The second memory chips 112a, 112b and 112c may not be directly connected to the external interconnection structure 410. As a second sub pad 522 and a second sub pad 522 are connected through a first internal interconnection structure 420 or a second sub pad 522 and a second main pad 521 are connected, a path for data signal transmission to the second memory chips 112a, 112b and 112c may be implemented.

The first memory chip 111 and the second memory chips 112a, 112b and 112c may include power pads 513, 523a, 523b and 523c, respectively.

The power pad 513 disposed in the first memory chip 111 may be electrically connected to the power management integrated circuit 130 through a power interconnection structure 440. The power interconnection structure 440 may connect the power pad 513 and a conductor ball 220, and may provide a path for power supply.

Each of the power pads 523a, 523b and 523c disposed in the second memory chips 112a, 112b and 112c may be electrically connected to the power management integrated circuit 130 through a power interconnection structure 440.

Each of the power pads 513, 523a, 523b and 523c included in the first memory chip 111 and the second memory chip 112a, 112b and 112c, respectively, may be electrically connected to the power management integrated circuit 130 through the separate power interconnection structure 440.

As the connection structures of a path for data signal transmission and a path for power supply are differentiated, it is possible to reduce the delay of a data signal transmission while maintaining the power supply efficiency.

In some embodiments of the disclosed technology, since each of the plurality of memory chips 110 included in the semiconductor system 100 includes a main pad and a sub pad and a pad for data signal transmission from the controller 120 and a pad for data signal transmission between the plurality of memory chips 110 are differentiated, it is possible to reduce or minimize the parasitic capacitance caused by a pad and a wire that constitute a data signal transmission path.

Parasitic capacitance in a data signal transmission path may be reduced by providing a connection structure using a sub pad having a different electrostatic discharge characteristic from a main pad, and accordingly, it is possible to provide the semiconductor system 100 capable of processing a large amount of data at a high speed by reducing the data signal transmission delay.

In this way, the disclosed technology can be implemented in some embodiments to provide a semiconductor system capable of reducing parasitic capacitance of a path through which a data signal is transmitted, thereby preventing/reducing transmission delay of data, and processing high-capacity data at high speed.

Only a few embodiments and examples are described. Enhancements and variations of the disclosed embodiments and other embodiments can be made based on what is described and illustrated in this patent document.

What is claimed is:

1. A semiconductor system comprising:
a substrate;
a first memory chip supported by the substrate, wherein the first memory chip includes a first main pad structured to be electrically connected to an interconnection structure disposed outside the first memory chip and a first sub pad electrically connected to the first main pad; and
one or more second memory chips supported by the substrate, wherein each of the one or more second memory chips includes a second main pad structured to be electrically connected to an interconnection structure disposed outside the first memory chip and a second sub pad electrically connected to the second main pad, and the second main pad or the second sub pad included in one second memory chip of the one or more second memory chips is electrically connected to the first sub pad by a first internal interconnection structure.

2. The semiconductor system according to claim 1, wherein the second sub pad included in the one second memory chip of the one or more second memory chips is electrically connected to the first sub pad by the first internal interconnection structure, and is electrically connected to the second sub pad included in another second memory chip of the one or more second memory chips by a second internal interconnection structure.

3. The semiconductor system according to claim 1, wherein second sub pads included in two adjacent second memory chips, respectively, of the one or more second memory chips are electrically connected by a second internal interconnection structure.

4. The semiconductor system according to claim 1, wherein
the second main pad included in the one second memory chip of the one or more second memory chips is electrically connected to the first sub pad by the first internal interconnection structure, and
the second sub pad included in the one second memory chip of the one or more second memory chips is electrically connected to the second main pad included in another second memory chip of the one or more second memory chips by a second internal interconnection structure.

5. The semiconductor system according to claim 1, wherein the second main pad included in one second memory chip of two adjacent second memory chips of the one or more second memory chips and the second sub pad included in the other second memory chip of the two adjacent second memory chips are electrically connected by a second internal interconnection structure.

6. The semiconductor system according to claim 1, wherein
the one or more second memory chips are divided into a first group and a second group,
respective second sub pads of second memory chips included in the first group are electrically connected to each other by a second internal interconnection structure, and respective second sub pads of second memory chips included in the second group are electrically connected to each other by a second internal interconnection structure, and
the second sub pad of one of the second memory chips included in the first group and the second main pad of one second memory chip of the second memory chips included in the second group are electrically connected to each other by a third internal interconnection structure.

7. The semiconductor system according to claim 1, wherein
the first memory chip includes a first main input diode and a first main output diode electrically connected to the first main pad, and
an output terminal of the first main input diode is electrically connected to an input terminal of the first main output diode.

8. The semiconductor system according to claim 7, wherein
the first memory chip includes a first sub input diode and a first sub output diode electrically connected to the first sub pad, and
an input terminal of the first sub input diode is electrically connected to the input terminal of the first main output diode.

9. The semiconductor system according to claim 8, wherein an output terminal of the first sub input diode is not electrically connected to an input terminal of the first sub output diode.

10. The semiconductor system according to claim 8,
wherein each of the one or more second memory chips includes:
a second main input diode and a second main output diode electrically connected to the second main pad; and
a second sub input diode and a second sub output diode electrically connected to the second sub pad, and
wherein an input terminal of the second sub input diode is electrically connected to an input terminal of the second main output diode.

11. The semiconductor system according to claim 1, wherein the first main pad is electrically connected to a controller configured to transmit a data signal to the first memory chip, by an external interconnection structure and a conductor ball.

12. The semiconductor system according to claim 11, wherein the external interconnection structure is directly connected to each of the first main pad and the conductor ball, and electrically connects the first main pad and the conductor ball to each other.

13. The semiconductor system according to claim 1, wherein an electrostatic discharge characteristic of each of the first sub pad and the second sub pad is lower than an electrostatic discharge characteristic of each of the first main pad and the second main pad.

14. The semiconductor system according to claim 1, wherein a size of the first sub pad is smaller than a size of the first main pad, and a size of the second sub pad is smaller than a size of the second main pad.

15. The semiconductor system according to claim 1, wherein a size of the second main pad is identical to a size of the first main pad, and a size of the second sub pad is identical to a size of the first sub pad.

16. The semiconductor system according to claim 1, wherein each of the first memory chip and the one or more second memory chips includes at least one power pad connected to a separate power supply interconnection structure.

17. A semiconductor chip comprising:
a main data pad having a first electrostatic discharge characteristic, and configured to receive a data signal from an external device outside the semiconductor chip; and
a sub data pad having a second electrostatic discharge characteristic lower than the first electrostatic discharge characteristic, and electrically connected to the main data pad, and configured to transmit the data signal to circuitry in semiconductor chip through sub data pad.

18. The semiconductor chip according to claim 17, further comprising:
a main input diode and a main output diode electrically connected to the main data pad,
wherein an output terminal of the main input diode is electrically connected to an input terminal of the main output diode.

19. The semiconductor chip according to claim 18, further comprising:
a sub input diode and a sub output diode electrically connected to the sub data pad,
wherein an input terminal of the sub input diode is electrically connected to the input terminal of the main output diode.

20. The semiconductor chip according to claim 17, wherein a size of the sub data pad is smaller than a size of the main data pad.
